(19) United States
(12) Patent Application Publication
(10) Pub. No.: US 2017/0054423 A1
(43) Pub. Date: Feb. 23, 2017

(54) Amplifier Device

(71) Applicant: Technetix B.V., Veenendaal (NL)

(72) Inventors: Jan Ariesen, Veenendaal (NL); Gerrit Boskaljon, Veenendaal (NL); Martien Rijssemus, Veenendaal (NL)

(21) Appl. No.: 15/118,960

(22) PCT Filed: Dec. 24, 2014
(86) PCT No.: PCT/EP2014/079317

§ 371 Date: Aug. 15, 2016

(30) Foreign Application Priority Data
Feb. 20, 2014 (GB) 1402998.7

(51) Int. Cl. H03F 3/62; H03F 1/48

(52) U.S. Cl. CPC H03F 3/62; H03F 1/486; H03F 2200/168; H03F 2200/165; H03F 2200/63; H04N 7/102

(57) ABSTRACT

There is provided an amplifier device for a CATV network comprising a first amplifier element for upstream signals and a second amplifier element for downstream signals, wherein the first and second amplifier elements are disposed between first and second directional couplers. The combined isolation of the first and second directional couplers is greater than the sum of the gain of the first and second amplifier elements. The first directional coupler has one port attached to an input of the downstream amplification element and one port attached to an output of an upstream amplification element (38) and the second directional coupler has one port attached to an output of the downstream amplifier and one port attached to an input of the upstream amplifier.

### CROSS-REFERENCE TO RELATED APPLICATIONS

The present application claims priority under 35 U.S.C. §371 of International Application No. PCT/EP2014/079317, filed Dec. 24, 2014, which claims priority to Great Britain Application No. 1402998.7, filed Feb. 20, 2014, the disclosures of which are hereby expressly incorporated by reference herein in their entireties.

### FIELD OF THE INVENTION

The present invention relates to an amplifier device for use in cable television and broadband networks.

### BACKGROUND TO THE INVENTION

In a broadband network, amplifiers are used to amplify electromagnetic signals travelling from a central network head end down to an individual user (downstream) or from the user back to the head end (upstream). The downstream and upstream signals are separated in frequency range, the upstream signals using a lower frequency band and the downstream using a higher frequency band. As amplifiers work in one direction and the electromagnetic signals within the network travel in two directions, separate amplifiers are needed for the downstream and upstream signals.

Currently, there are several industry standards for the frequency split between upstream and downstream signals such as 42/54 (up to 42 MHz for upstream, 54 MHz and higher for downstream) and 65/85 MHz split. In new technologies such as DOCSIS 3.0, the frequency split is 85/105 MHz and with DOCSIS 3.1, the frequency split can go up to 200 MHz or 400 MHz for the upstream signals.

The frequency split between upstream and downstream signals is likely to be altered in the future to give homes a faster, more wideband upstream signal, such as with a frequency split of 200/250 MHz. However, each change in the frequency split, network components such as signal filters within amplifiers need to be altered which can be time-consuming and expensive.

### SUMMARY OF THE INVENTION

In accordance with the present invention, there is provided an amplifier device for a CATV network comprising a first amplifier element for upstream signals and a second amplifier element for downstream signals, wherein the first and second amplifier elements are disposed between first and second directional couplers. By using directional couplers, diplex filters are not needed to separate upstream and downstream paths.

Preferably, the combined isolation of the first and second directional couplers is greater than the sum of the gain of the first and second amplifier elements. The construction is chosen to ensure the isolation is also high enough even when the home side of the amplifier is not terminated. This avoids oscillation effects due to signal leakage between the first and second directional couplers.

The first directional coupler may have one port attached to an input of the downstream amplification element and one port attached to the output of the upstream amplification element and the second directional coupler may have one port attached to an output of the downstream amplifier and one port attached to an input of the upstream amplifier. In this way, the pair of directional couplers provides separated unidirectional path sections in which the unidirectional amplifier elements are disposed.

A high pass filter may be disposed between the first directional coupler and the first amplifier element. Typically, the high pass filter will be configured to pass signals of 54 MHz and above, i.e., the lowest downstream frequency used at present. By using a high pass filter, the isolation for low frequencies can be improved.

The amplifier device may further comprise a low pass filter disposed between the second directional coupler and the second amplification element. This improves isolation and the low pass filter is selected to let the maximum upstream frequency through, and thus will typically allow 200 or even 400 MHz to pass through the filter as this is the expected bottom end of the downstream signals band.

The amplifier is preferably a bidirectional wideband amplifier.

### BRIEF DESCRIPTION OF THE DRAWINGS

The present invention will now be described by way of example and with reference to the accompanying drawings in which:

FIG. 1 shows a schematic diagram of a prior art amplifier device;

FIG. 2 shows a schematic diagram of a first embodiment of an amplifier device in accordance with the present invention;

FIG. 3 shows a schematic diagram of a second embodiment; and

FIG. 4 shows a schematic diagram of the third embodiment.

### DETAILED DESCRIPTION OF THE INVENTION

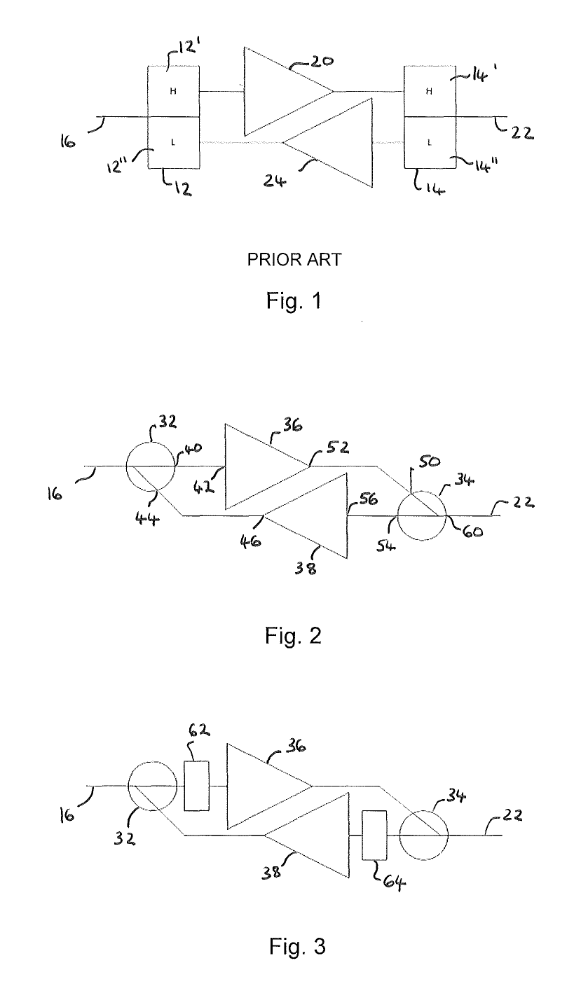

A prior art bidirectional frequency amplifier 10 for upstream and downstream signals is shown in FIG. 1 comprising diplex filters 12, 14 used to separate the low frequency and high frequency signal bands into separate unidirectional pathways for amplification by unidirectional amplifier elements 20, 24. Downstream signals from network 16 are configured at a higher frequency band than the return or upstream signals and passes through high pass side 12′ of filter 12 through amplifier element 20 and high pass side 14′ of filter 14 to reach a subscriber or user's home. The return or upstream signal from home 22 is filtered through low pass side 14″ of filter 14 to reach amplifier element 24 and pass through low pass side 12″ of filter 12 to reach network 16.

In future, the frequency split between the upstream and downstream frequency bands will change, for example, from 65/85 or 42/54 to a much higher frequency, for instance 200/250 MHz. This will give a user a faster, more wideband upstream signal.

When the split frequency between upstream and downstream signals changes, diplex filters 12, 14 will need to be replaced with new filters to accommodate the altered frequency bands. To change diplex filters integrated within an amplifier is difficult and typically the complete amplifier is replaced.

An amplifier is now disclosed where diplex filters are not used to separate the upstream and downstream frequency signals for amplification. As shown in FIG. 2, amplifier 30 comprises a pair of directional couplers 32, 34 connected together to create two separate electrical paths, a single unidirectional amplifier element 36, 38 being disposed in each path.

The first directional coupler, or tap, 32 is connected to network 16 and has one port 40 connected to input port 42 of amplifier element 36 and a second port 44 connected to output 46 of amplifier element 38. A second directional coupler or tap 34 has one port 50 connected to output 52 of amplifier 36 and a second port 54 connected to input 56 of amplifier element 38. The remaining port 60 of tap 34 is connected to a subscriber's home output 22.

Incoming signal from network 16 (downstream signal) passes through directional coupler 32 to amplifier element 36. The signal is amplified and directed through tap port 50 of directional coupler 34 to home connection 22. The upstream signal from home connection 22 to cable network 16 passes through tap 34 to reach amplifier element 38 where the upstream signal is amplified and passed to tap 32 to reach network 16.

The interconnection of the two directional couplers 32, 34 provides separated unidirectional downstream and upstream signal pathways. This ensures both upstream and downstream signals can be amplified in the correct direction by oppositely orientated amplifier elements without the use of diplex filters. When the network is upgraded to have altered frequency splits between upstream and downstream signal bands, the amplifier does not have to be replaced as there are no diplex filters sensitive to the specific frequencies used.

Directional coupler 34 has directivity and a high isolation, often more than 30 to 50 dB, but part of the downstream signal will leak to input 56 of amplifier element 38. Although the leaked signal will be small as the isolation is very high, the leaked signal is amplified again in amplifier element 38 and fed to network 16 via directional coupler tap 32. Again, a part of the signal can leak through tap 32 and reach input 42 of amplifier element 36. This causes a risk that amplifier 30 might oscillate, producing an unwanted signal that can disturb the normal signals. However, as long as the sum of the isolation of tap 32 and tap 34 is much higher than the sum of the gain of amplifier element 36 and amplifier element 38, oscillation will not occur.

If desired, filters can be positioned between the directional couplers and within the separated unidirectional pathways to improve isolation. Thus, a high pass filter 62 can be added at the input of downstream amplifier element 36 to provide extra isolation on the lower frequencies, see FIG. 3. High pass filter 62 is selected to pass the lowest downstream frequency used at the moment, i.e., 54 MHz.

Similarly, for upstream amplifier element 38, a low pass filter 64 can be added. The highest frequency used in the future (200 or 400 MHz) determines the maximum frequency of low pass filter 64.

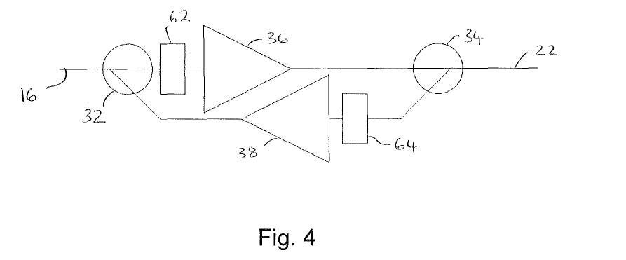

The directional couplers can be positioned differently, see FIG. 4, as long as the isolation of the two directional couplers are high enough to avoid oscillation. The position of the directional couplers will depend on the required upstream and downstream gain.

Using such an amplifier as shown in FIGS. 2, 3 and 4 avoids the need to change the amplifier when the frequency band split for upstream and downstream changes Amplifier 30 will work in all international used split frequencies from 42/54 to 200/250 or even 400/500 MHz and everything inbetween and changes in frequency split can simply be enacted overnight without any intervention required to the in-home network.

While the present invention has been illustrated by description of various embodiments and while those embodiments have been described in considerable detail, it is not the intention of Applicant to restrict or in any way limit the scope of the appended claims to such details. Additional advantages and modifications will readily appear to those skilled in the art. The present invention in its broader aspects is therefore not limited to the specific details and illustrative examples shown and described. Accordingly, departures may be made from such details without departing from the spirit or scope of Applicants' invention.

What is claimed is:

1. An amplifier device for a CATV network, comprising:
a first amplifier element for upstream signals; and
a second amplifier element for downstream signals,
wherein the first and second amplifier elements are disposed between first and second directional couplers.

2. The amplifier device according to claim 1, wherein the combined isolation of the first and second directional couplers is greater than the sum of the gain of the first and second amplifier elements.

3. The amplifier device according to claim 1, wherein the first directional coupler has one port attached to an input of the downstream amplification element and one port attached to the output of an upstream amplification element and the second directional coupler has one port attached to an output of the downstream amplifier and one port attached to an input of the upstream amplifier.

4. The amplifier device according to claim 1, wherein a high pass filter is disposed between the first directional coupler and the first amplifier element.

5. The amplifier device according to claim 1, wherein a low pass filter is disposed between the second directional coupler and the second amplification element.

6. The amplifier device according to claim 1, wherein the amplifier device comprises a bidirectional wideband amplifier.
